(19) United States
(12) Patent Application Publication
(10) Pub. No.: US 2026/0169087 A1
(43) Pub. Date: Jun. 18, 2026

(54) DEEP LEARNING-BASED STATE OF HEALTH AND REMAINING USEFUL LIFE PREDICTION SYSTEM

(71) Applicant: IUCF-HYU (INDUSTRY-UNIVERSITY COOPERATION FOUNDATION HANYANG UNIVERSITY), Seoul (KR)

(72) Inventors: Suk Joo BAE, Seoul (KR); Sun Geu CHAE, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/367,116

(22) Filed: Oct. 23, 2025

(30) Foreign Application Priority Data
Dec. 18, 2024 (KR) 10-2024-0190196

(51) Int. Cl. G01R 31/392; G01R 31/367; G06N 3/0985

(52) U.S. Cl. CPC G01R 31/392; G01R 31/367; G06N 3/0985

(57) ABSTRACT

According to one embodiment of the present disclosure, the system for predicting a state of health and a remaining useful life of a battery based on deep learning, comprises a database configured to store first aggregate data including multiple battery data collected from an input unit; and a processor configured to preprocess the first aggregate data based on a first artificial intelligence model, train a second artificial intelligence model with the preprocessed first aggregate data as input, and predict a state of health (SoH) and a remaining useful life (RUL) of a battery based on the second artificial intelligence model that has completed training, wherein the processor comprises a preprocessing unit configured to preprocess the first aggregate data by converting the first aggregate data into a spectrogram and denoising based on the first artificial intelligence model; a training unit configured to extract features with the preprocessed first aggregate data as input, and proceed with training the second artificial intelligence model to estimate the state of health based on the extracted features; and a prediction unit configured to estimate the state of health and predict the remaining useful life from second aggregate data input by a user based on the second artificial intelligence model trained by the training unit.

### CROSS-REFERENCE TO RELATED APPLICATION

This application claims priority under 35 U.S.C §119 to Korean Patent Application No. 10-2024-0190196 filed on Dec. 18, 2024, in the Korean Intellectual Property Office, the entire contents of which are hereby incorporated by reference.

### TECHNICAL FIELD

One disclosed embodiment relates to a system for predicting the state of health and remaining useful life of a battery based on a deep learning model.

### BACKGROUND

Lithium-ion batteries, thanks to their high energy density and long service life, play a key role in a variety of applications, such as electric vehicles, energy storage systems (ESS), and consumer electronics. However, batteries accumulate physical and chemical degradation during the charging and discharging process, which not only reduces performance and shortens their service life, but can also pose safety issues in severe cases. Therefore, technology that accurately assesses a battery’s state of health (SoH) and predicts its remaining useful life (RUL) is essential to ensuring battery reliability and stability.

Conventional technologies for predicting the state of health and remaining useful life of a battery can be broadly categorized into equivalent circuit models (ECMs), physics-based models, and data-driven models. An equivalent circuit model is a method of estimating a battery’s state of health (SoH) by modeling the electrical characteristics of the battery into a simple circuit. This method is advantageous in that calculation speed is fast and implementation is simple, but it is limited in prediction accuracy as it fails to fully reflect the complex physical and chemical change processes of battery degradation. A physics-based model is a method of calculating the state of health (SoH) and remaining useful life (RUL) of a battery by mathematically modeling the chemical reactions and physical degradation mechanisms inside the battery. This model offers high theoretical accuracy; however, it is disadvantageous in that it requires detailed information on the internal structure and operating conditions of the battery, and the computational costs are very high. A data-driven model is a method of predicting the state of health (SoH) and remaining useful life (RUL) of a battery by learning based on large-scale data of the battery. This model is highly flexible in that it automatically extracts features from data without relying on a fixed mathematical model, but it still has limitations in the efficiency of feature extraction and the generalization capability of the model.

These conventional technologies share several common drawbacks. First, they fail to effectively learn or reflect the nonlinear characteristics of battery degradation and the diverse patterns resulting from environmental factors. Second, most of the methods exhibit reliable performance only on static data or in limited experimental environments, lacking generalization capability in real-world operating environments. Third, many technologies rely on labeled data and suffer from a significant reduction in performance in environments in which large-scale, high-quality data is lacking. Lastly, conventional technologies have difficulty estimating a battery’s state of health (SoH) or predicting its remaining useful life (RUL) in real time, resulting in limitations in optimizing battery life management and maintenance planning.

### SUMMARY

### TECHNICAL OBJECTS

In order to overcome the limitations of the conventional technologies described above, one disclosed embodiment relates to a system that denoises battery data by using a deep learning model and predicts the state of health (SoH) and remaining useful life (RUL) of a battery.

### TECHNICAL SOLUTION

According to one embodiment of the present disclosure, the system for predicting a state of health and a remaining useful life of a battery based on deep learning, comprises a database configured to store first aggregate data including multiple battery data collected from an input unit; and a processor configured to preprocess the first aggregate data based on a first artificial intelligence model, train a second artificial intelligence model with the preprocessed first aggregate data as input, and predict a state of health (SoH) and a remaining useful life (RUL) of a battery based on the second artificial intelligence model that has completed training, wherein the processor comprises a preprocessing unit configured to preprocess the first aggregate data by converting the first aggregate data into a spectrogram and denoising based on the first artificial intelligence model; a training unit configured to extract features with the preprocessed first aggregate data as input, and proceed with training the second artificial intelligence model to estimate the state of health based on the extracted features; and a prediction unit configured to estimate the state of health and predict the remaining useful life from second aggregate data input by a user based on the second artificial intelligence model trained by the training unit.

The first and second aggregate data comprise voltage, charge/discharge capacity, and current.

The preprocessing unit converts the first aggregate data into a spectrogram by using a short-time Fourier transform (STFT).

The system of claim 3, wherein the preprocessing unit denoises the converted spectrogram data based on a denoising convolutional neural network (DnCNN).

The training unit: receives data generated by the preprocessing unit as input, and extracts a feature vector and trains the second artificial intelligence model to estimate the state of health (SoH) based on the feature vector.

The training unit optimizes hyperparameters, including a learning rate, a dropout rate, and a batch size, by applying Bayesian optimization in a process of training the second artificial intelligence model.

The prediction unit: based on the second artificial intelligence model trained by the training unit, estimates the state of health (SoH) in real time from the second aggregate data input by the user, and predicts the remaining useful life (RUL) based on a result of estimating the state of health.

According to another embodiment of the present disclosure, the method of predicting a state of health and a remaining useful life of a battery based on deep learning, comprisies storing multiple data received from an input unit as first aggregate data; converting the first aggregate data into a spectrogram; preprocessing and denoising data by inputting the converted spectrogram data into a first artificial intelligence model; proceeding with training a second artificial intelligence model to estimate a state of health (SoH) of a battery by inputting the denoised data into the second artificial intelligence model; and estimating the state of health (SoH) and predicting a remaining useful life (RUL) of the battery from second aggregate data input by a user based on the trained second artificial intelligence model.

The converting into the spectrogram converts the first aggregate data into two-dimensional data including time-frequency domain features based on a short-time Fourier transform (STFT).

The first artificial intelligence model is a denoising convolutional neural network that applies a residual learning technique.

The first artificial intelligence model comprises at least one of a denoising convolutional neural network (DnCNN), a flexible and fast denoising network (FFDNet), and a memory network (MemNet).

The second artificial intelligence model comprises at least one of a convolutional neural network (CNN), a recurrent neural network (RNN), a variational autoencoder (VAE), and a transformer.

According to the other embodiment of the present disclosure, A system for predicting a state of health and a remaining useful life of a battery based on deep learning, comprises a database configured to store first aggregate data including multiple data received from an input unit; a processor configured to convert the first aggregate data into a spectrogram, denoise by inputting the converted spectrogram data into a first artificial intelligence model, estimate a state of health (SoH) of a battery by inputting the denoised first aggregate data into a second artificial intelligence model, and predict a remaining useful life (RUL) of the battery; and an output unit configured to output a result of predicting the state of health (SoH) and the remaining useful life (RUL) from second aggregate data input by a user based on the first and second artificial intelligence models that have been trained.

The processor detects a deterioration in battery health based on the result of predicting the state of health (SoH), and provides a detection result.

The processor generates a battery maintenance plan including battery replacement timing based on the result of predicting the remaining useful life (RUL), and provides the generated maintenance plan.

### EFFECTS OF THE DISCLOSURE

The deep learning-based state of health and remaining useful life prediction system according to one disclosed embodiment can denoise battery data and predict the state of health (SoH) and remaining useful life (RUL) of a battery with high accuracy. Thereby, the following advantages are provided.

First, the deep learning-based state of health and remaining useful life prediction system according to one disclosed embodiment can accurately predict the SoH and RUL by improving data quality by denoising battery data based on a denoising convolutional neural network (DnCNN) and by learning complex degradation patterns through a deep learning model such as a convolutional neural network (CNN) or a transformer. In particular, high reliability is maintained in a variety of battery usage environments and conditions.

Second, the deep learning-based state of health and remaining useful life prediction system according to one disclosed embodiment significantly improves efficiency and accuracy compared to existing manual feature extraction methods by automatically extracting features from large-scale data and evaluating the state of the battery in real time. This is superior in adaptability and versatility to constant current charge/discharge analysis or equivalent circuit models.

Third, the deep learning-based state of health and remaining useful life prediction system according to one disclosed embodiment can detect the initial degradation state of a battery at an early stage, thereby improving safety and preventing risks such as battery explosion in advance. Further, cost reduction and resource efficiency is provided by optimizing battery replacement timing and maintenance plans.

Lastly, the deep learning-based state of health and remaining useful life prediction system according to one disclosed embodiment can be readily integrated with a battery management system (BMS), and can contribute to improving battery performance management and reliability in a variety of applications, such as electric vehicles, energy storage systems (ESS), and consumer electronics. Thereby, a battery’s service life can be extended and user convenience and safety can be enhanced.

### BRIEF DESCRIPTION OF THE DRAWINGS

FIG. 1 is a diagram for broadly describing a disclosed deep learning-based state of health and remaining useful life prediction system;

FIG. 2 is a control block diagram of the disclosed deep learning-based state of health and remaining useful life prediction system;

FIG. 3 is a flowchart showing a process in which a processor receives aggregate data and predicts the state of health and remaining useful life of a battery;

FIG. 4 is a diagram for specifically describing the operation of a preprocessing unit; and

FIG. 5 is a diagram for specifically describing the operation of a training unit and a prediction unit.

### DETAILED DESCRIPTION OF THE PREFERRED EMBODIMENTS

The same reference numerals throughout the specification refer to the same components. This specification does not describe all elements of the embodiments, and common or repetitive content between the embodiments or in the relevant technical field is omitted.

It will be understood that when an element is referred to as being "connected" another element, it can be directly or indirectly connected to the other element, wherein the indirect connection includes "connection via a wireless communication network".

Also, when a part "includes" or "comprises" an element, unless there is a particular description contrary thereto, the part may further include other elements, not excluding the other elements.

Throughout the description, when a member is "on" another member, this includes not only when the member is in contact with the other member, but also when there is another member between the two members.

Additionally, terms like '~unit', '~device', '~block', '~component', and '~module' can refer to a unit that handles at least one function or operation. For example, the aforementioned terms may refer to at least one hardware component, such as an FPGA (field-programmable gate array) or an ASIC (application-specific integrated circuit), or at least one software stored in memory, or at least one process handled by a processor.

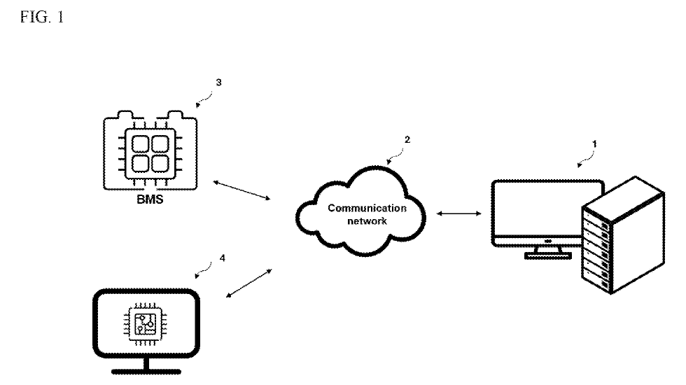

An identification code is used for the convenience of the description but is not intended to illustrate the order of each step. The each step may be implemented in the order different from the illustrated order unless the context clearly indicates otherwise.FIG. 1 is a diagram for broadly describing a disclosed deep learning-based state of health and remaining useful life prediction system.

FIG. 1 is a diagram for broadly describing a disclosed deep learning-based state of health and remaining useful life prediction system.

Referring to FIG. 1, the deep learning-based state of health and remaining useful life prediction system 1 according to one disclosed embodiment may be implemented as a computer or portable terminal capable of collecting battery data, including voltage, resistance, temperature, discharge capacity, charge capacity, and current, from external devices 3 and 4 via a communication network 2. Here, the computer may include, for example, a desktop, a laptop, a tablet PC, a slate PC, and the like equipped with a web browser, and the portable terminal is, for example, a wireless communication device that ensures portability and mobility, and may include any type of handheld-based wireless communication device, such as a PCS (personal communication system), GSM (Global System for Mobile communications), PDC (Personal Digital Cellular), PHS (Personal Handy-phone System), PDA (personal digital assistant), IMT (International Mobile Telecommunication)-2000, CDMA (code-division multiple access)-2000, W-CDMA (wideband code-division multiple access), and WiBro (wireless broadband Internet) terminal, a smartphone, and the like, and a wearable device, such as a watch, a ring, a bracelet, an anklet, a necklace, eyeglasses, contact lenses, a head-mounted device (HMD), or the like.

The deep learning-based state of health and remaining useful life prediction system 1 may collect battery data, including voltage, resistance, temperature, discharge capacity, charge capacity, and current, from a battery management system (BMS) 3 and a personal computer 4.

Specifically, the battery management system (BMS) is a component that measures battery data and may collect battery data, including voltage, resistance, temperature, discharge capacity, charge capacity, and current.

The personal computer 4 is a component that can collect battery data held by users on their individual terminals, and is a component for describing that battery data collected not only currently but also in the past can be utilized as training data.

The battery data collected from the respective devices 3 and 4 is transmitted to the deep learning-based state of health and remaining useful life prediction system 1 via the communication network 2.

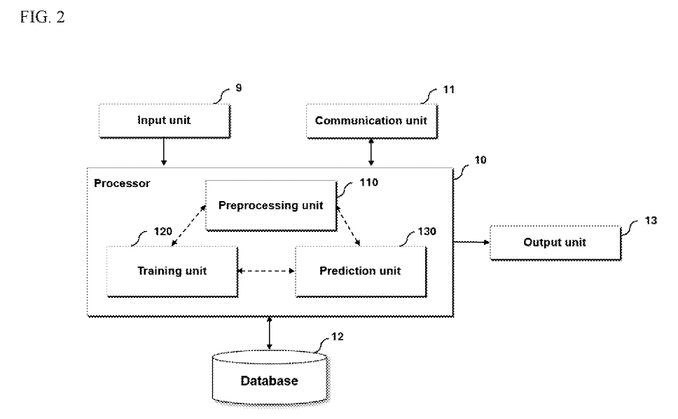

The communication network 2 is a path for receiving data from the components 3 and 4 described above, and the deep learning-based state of health and remaining useful life prediction system 1 receives data from the communication network 2. The multiple battery data received in this way are stored in a database 12 (see FIG. 2) of the deep learning-based state of health and remaining useful life prediction system 1. The deep learning-based state of health and remaining useful life prediction system 1 may denoise the data stored in the database 12 by using a deep learning model, and predict the state of health (SoH) and remaining useful life (RUL) of the battery. The specific operations and methods by which the deep learning-based state of health and remaining useful life prediction system 1 determines the state of health and predicts the remaining useful life will be described later with reference to other drawings below.

On the other hand, in addition to the components 3 and 4 shown in FIG. 1, the deep learning-based state of health and remaining useful life prediction system 1 may receive battery data from various devices capable of storing data, such as smartphones, laptops, or tablet PCs, and may also receive various types of battery data from web or cloud servers, and the like. Further, the deep learning-based state of health and remaining useful life prediction system 1 may also collect voice data directly from the user via a peripheral device, such as Universal Serial Bus (USB), without going through the communication network 2.

FIG. 2 is a control block diagram of the disclosed deep learning-based state of health and remaining useful life prediction system.

Referring to FIG. 2, the deep learning-based state of health and remaining useful life prediction system 1 includes an input unit 9 that collects battery data, a communication unit 11 that performs communication with the communication network 2, a database 12 that stores aggregate data (hereinafter, “first aggregate data”) including multiple battery data collected from the input unit 9 or the communication unit 11, a first artificial intelligence model that preprocesses the first aggregate data by converting it into a spectrogram and denoising it, and a second artificial intelligence model that predicts the state and remaining useful life of the battery from the preprocessed first aggregate data, a processor 10 that preprocesses the first aggregate data stored in the database 12, then trains an artificial intelligence model, and predicts the state and remaining useful life of the battery based on the trained artificial intelligence model, and an output unit 13 that outputs the results of predicting the state and remaining useful life of the battery based on aggregate data (hereinafter, “second aggregate data”) newly received by the user.

Specifically, the input unit 9 may include hardware devices, such as various buttons or switches, a pedal, a keyboard, a mouse, a trackball, various levers, a handle or stick, etc., to receive user input.

As one example, the input unit 9 may receive whether to train an artificial intelligence model with the first aggregate data or whether to detect abnormal battery degradation based on the second aggregate data by using the trained artificial intelligence model.

The communication unit 11 may include various components that enable the deep learning-based state of health and remaining useful life prediction system 1 to communicate with external devices (3 and 4 in FIG. 1), and may include, for example, at least one of a short-range communication module, a wired communication module, and a wireless communication module.

The short-range communication module may include various short-range communication modules that transmit and receive signals using a wireless communication network in short ranges, such as a Bluetooth module, an infrared communication module, an RFID (radio frequency identification) communication module, a WLAN (wireless local access network) communication module, an NFC communication module, and a Zigbee communication module.

The wired communication module may include various wired communication modules, such as a local area network (LAN) module, a wide area network (WAN) module, or a value-added network (VAN) module, as well as various cable communication modules, such as Universal Serial Bus (USB), High Definition Multimedia Interface (HDMI), Digital Visual Interface (DVI), Recommended Standard 232 (RS-232), power line communication, or plain old telephone service (POTS).

The wireless communication module may include a wireless communication module that supports a variety of wireless communication schemes, such as Global System for Mobile Communication (GSM), code-division multiple access (CDMA), wideband code-division multiple access (WCDMA), Universal Mobile Telecommunications System (UMTS), time-division multiple access (TDMA), and long-term evolution (LTE), in addition to a Wi-Fi module and a Wireless Broadband (WiBro) module.

The database 12 stores not only various aggregate data collected by the input unit 9 or the communication unit 11, but also the first artificial intelligence model for preprocessing the aggregate data, the second artificial intelligence model for predicting the state of health and remaining useful life from the preprocessed aggregate data, an artificial intelligence model to be trained with the aggregate data, and an artificial intelligence model that has completed training.

The database 12 may be implemented with at least one of a non-volatile memory device such as cache, read-only memory (ROM), programmable ROM (PROM), erasable programmable ROM (EPROM), electrically erasable programmable ROM (EEPROM), and flash memory, a volatile memory device such as random access memory (RAM), or a storage medium such as a hard disk drive (HDD) or CD-ROM, but is not limited thereto. The database 12 may be a memory implemented as a chip separate from the processor 10 as shown in FIG. 2, but may also be implemented as a single chip with the processor 10 as needed.

The output unit 13 outputs data including the results estimated by the processor 10, i.e., the results of predicting the state of health and remaining useful life of the battery based on the second aggregate data. For example, the output unit 13 may output a battery maintenance plan, including battery replacement timing, generated based on the prediction results via a user interface, while outputting the state of health and remaining useful life of the battery predicted from the battery data onto a screen via a display.

For the operations described above, the output unit 13 may include various hardware devices, such as a digital light processing (DLP) panel, a plasma display panel (PDP), a liquid crystal display (LCD) panel, an electroluminescence (EL) panel, an electrophoretic display (EPD) panel, an electrochromic display (ECD) panel, a light-emitting diode (LED) panel, or an organic light-emitting diode (OLED) panel.

Furthermore, the output unit 13 may include a GUI (graphical user interface), i.e., a software device, such as a touch pad or the like, for user input. The touch pad may be implemented as a touch screen panel (TSP) and form an interlayer structure with the input unit 9.

The processor 10 controls the entirety of the deep learning-based state of health and remaining useful life prediction system 1. To this end, the processor 10 may execute an algorithm for controlling the components shown in FIG. 2 or a program that reproduces the algorithm. In other words, the processor 10 refers to a data processing device embedded in hardware that has a physically structured circuit to perform functions represented by code or commands included in a program, and examples of such a data processing device embedded in hardware may encompass, but are not limited to, processing devices such as a microprocessor, a central processing unit (CPU), a processor core, a multiprocessor, an application-specific integrated circuit (ASIC), a field programmable gate array (FPGA), and a graphics processing unit (GPU). The processor 10 may be implemented with one or more chips.

The processor 10 may be divided software-wise into a preprocessing unit 110 that converts the first aggregate data into a spectrogram and denoises based on residual learning, a training unit 120 that extracts features based on the data generated by the preprocessing unit and trains an artificial intelligence model to predict the state and remaining useful life of the battery, and a prediction unit 130 that predicts the state and remaining useful life of the battery from the second aggregate data input by the user based on the artificial intelligence model trained by the training unit.

A detailed description of the operation of the processor 10, which is divided software-wise, will be provided later with reference to other drawings below.

On the other hand, the disclosed deep learning-based state of health and remaining useful life prediction system 1 may further include various components in addition to the components described above, and each component in FIG. 2 may be modified or combined in a variety of ways depending on the necessary operation.

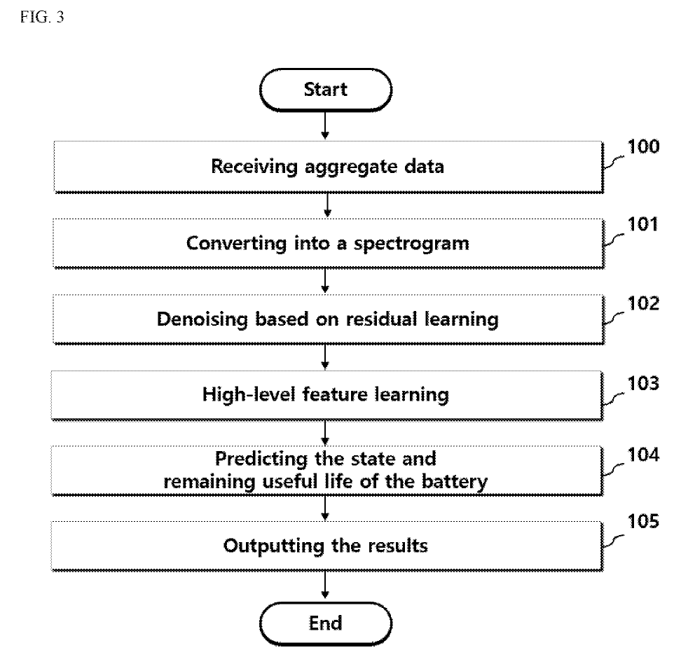

FIG. 3 is a flowchart showing a process in which the processor 10 of the disclosed deep learning-based state of health and remaining useful life prediction system 1 receives and converts aggregate data into a spectrogram, preprocesses it by denoising based on residual learning, and predicts the state and remaining useful life of the battery from the preprocessed data based on high-level feature learning.

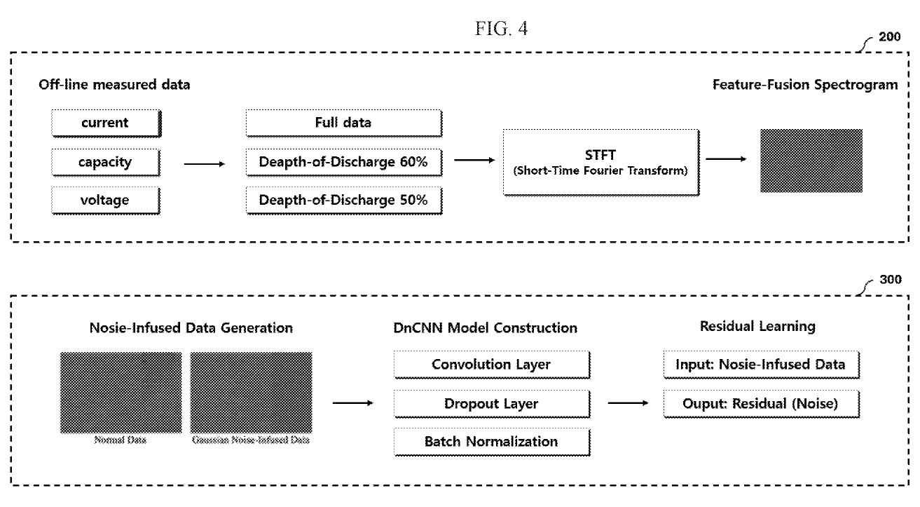

To avoid repetitive descriptions below, the process in which the deep learning-based state of health and remaining useful life prediction system 1 receives and preprocesses aggregate data will be described with concurrent reference to FIGS. 3 and 4.

Referring to FIG. 3, the deep learning-based state of health and remaining useful life prediction system 1 receives aggregate data (100).

Here, the aggregate data (hereinafter, “first aggregate data”) is data received from the input unit 9 or the communication unit 11, and may include voltage, charge/discharge capacity, and current. The first aggregate data may be data measured by respective sensors that measure voltage, charge/discharge capacity, and current in real time, and is used to train an artificial intelligence model in the training unit 120.

Specifically, the first aggregate data may be collected from data measured in real time via measurement equipment, such as a battery management system (BMS) 3. The battery management system (BMS) utilizes various sensors in order to measure battery data such as voltage, resistance, temperature, discharge capacity, charge capacity, and current. Voltage is measured via a voltage sensor, resistance is measured via an impedance analyzer or constant current circuit, temperature is measured via a thermocouple, a resistance temperature detector (RTD), or a negative temperature coefficient (NTC) thermistor, discharge and charge capacities are measured via a current sensor and data logger, and current is measured via a Hall effect current sensor or shunt resistor.

Referring to FIG. 3, the deep learning-based state of health and remaining useful life prediction system 1 preprocesses the received aggregate data (101).

Referring to FIG. 4, the deep learning-based state of health and remaining useful life prediction system 1 preprocesses the data by converting the voltage, charge/discharge capacity, and current data out of the first aggregate data into a spectrogram (200) and denoising it (300).

The deep learning-based state of health and remaining useful life prediction system 1 according to the disclosed embodiment may apply a short-time Fourier transform (STFT) in order to convert the voltage, charge/discharge capacity, and current data included in the first aggregate data into a spectrogram in the time-frequency domain. Thereby, the time-series characteristics of the battery data are represented in frequency components, enabling the deep learning model to effectively learn important features.

Specifically, the first aggregate data received via the input unit 9 or the communication unit 11 is divided into constant time windows. This time window is used as the basic unit for converting local features of the data into the frequency domain, and a Fourier transform is performed on each time window. At this time, the size of the time window is an important parameter that adjusts the resolution and temporal discriminability of the converted frequency components and is optimized to suit the characteristics of the battery data. A spectrogram is generated by computing the spectral magnitude of the STFT result. This spectrogram is represented in the form of a two-dimensional matrix, with the horizontal axis representing time, the vertical axis representing frequency, and the color or amplitude representing the signal strength at a particular time and frequency. The generated spectrogram reflects characteristic patterns that show up in various operating conditions (charge/discharge rates, temperature changes, etc.) of the battery data and is then utilized in the preprocessing step, including denoising.

The deep learning-based state of health and remaining useful life prediction system 1 according to the disclosed embodiment may use a denoising convolutional neural network (DnCNN) in order to denoise the data converted into a spectrogram. The denoising step using DnCNN improves the signal quality of the battery data and enables high-accuracy results to be derived in the subsequent training and prediction processes of the deep learning model.

DnCNN uses a residual learning technique in order to learn and remove noise components from input data. To describe more specifically, DnCNN receives spectrogram data, passes it through several convolutional layers and rectified linear units (ReLUs), and extracts key features of the battery data at each layer. As described above, DnCNN operates in the manner of predicting residuals and removing them from the input data. Thereby, abnormal signals, such as Gaussian noise or spike noise, contained in the battery data can be effectively removed.

The data preprocessed through denoising can provide high reliability and accuracy in predicting the state of health (SoH) and remaining useful life (RUL) of the battery by keeping the spatiotemporal features of the battery data and, at the same time, preventing the deep learning model from being confused by unnecessary signal components.

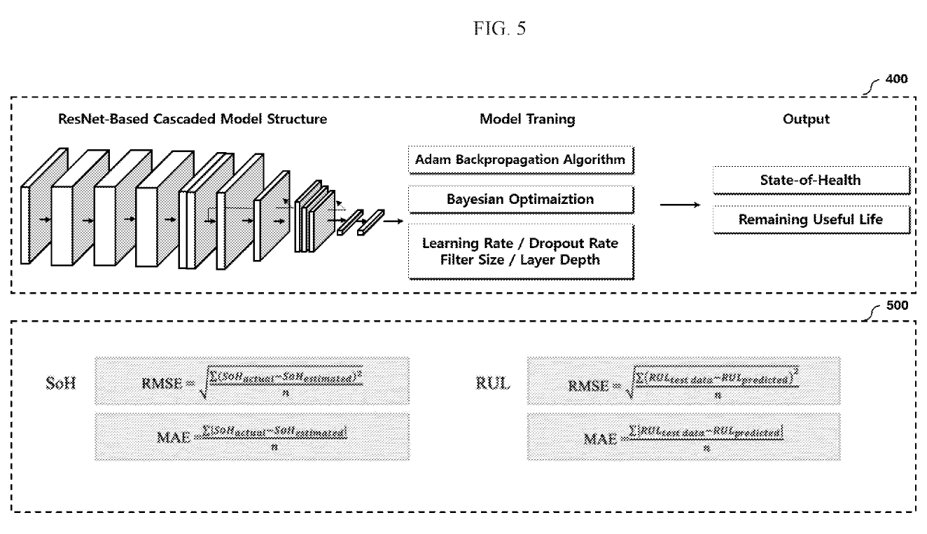

To avoid repetitive descriptions below, the process in which the deep learning-based state of health and remaining useful life prediction system 1 learns features based on the preprocessed data and predicts the state and remaining useful life of the battery will be described with concurrent reference to FIGS. 3 and 5.

Referring to FIG. 3, the deep learning-based state of health and remaining useful life prediction system 1 learns features with the preprocessed data as input (103) and predicts the state and remaining useful life of the battery (104).

Referring to FIG. 5, the deep learning-based state of health and remaining useful life prediction system 1 trains an artificial intelligence model based on the preprocessed data (400) and predicts the state and remaining useful life of the battery in the trained artificial intelligence model (500).

The deep learning-based state of health and remaining useful life prediction system 1 according to the disclosed embodiment trains a second artificial intelligence model with the spectrogram data denoised through the preprocessing step as input (400).

Specifically, the second artificial intelligence model is a predictive model that learns the state of health (SoH) and remaining useful life (RUL) of the battery based on the preprocessed first aggregate data, and may be at least one of a convolutional neural network (CNN), a recurrent neural network (RNN), a variational autoencoder (VAE), or a transformer.

The mean squared error (MSE) or cross-entropy loss may be used as the loss function in the training process of the second artificial intelligence model, and hyperparameters, including a learning rate, a batch size, and a dropout rate, may be optimized through Bayesian optimization.

The deep learning-based state of health and remaining useful life prediction system 1 according to the disclosed embodiment predicts the state and remaining useful life of the battery based on the second artificial intelligence model that has completed training (500).

Specifically, the second artificial intelligence model that has completed training estimates the state of the battery in real time based on the second aggregate data input by the user, and computes the remaining useful life (RUL) of the battery based on the predicted state of health (SoH). The prediction of the remaining useful life (RUL) is made by reflecting the degradation state and operating conditions of the battery, and provides high reliability even in various operating environments by precisely analyzing complex degradation patterns.

The deep learning-based state of health and remaining useful life prediction system 1 according to the disclosed embodiment outputs the results of predicting the state and remaining useful life of the battery based on the artificial intelligence model that has completed training (105).

In the disclosed embodiment, the output unit 13 may visually represent the state of health (SoH) and remaining useful life (RUL) of the battery predicted by the processor 10 based on a user interface (UI).

Specifically, the output unit 13 may display the state of the battery in real time, and may show the state of health (SoH) as a percentage (%) value and the remaining useful life (RUL) as an estimated remaining usage time or a charge/discharge cycle count. Further, the output unit 13 may also provide notifications, including warning messages and maintenance recommendations, if an abnormal state of the battery is detected.

The output unit 13 may share the predicted state of health (SoH) and remaining useful life (RUL) data through communication with an external system (e.g., the battery management system (BMS)) or a remote server.

Lastly, the output unit 13 can improve the efficiency of battery life management by providing the user with battery replacement timing or maintenance plans.

Such operation of the output unit 13 is merely one example, and various modifications are possible.

As a result, the disclosed deep learning-based state of health and remaining useful life prediction system 1 denoises the data received from the input unit and predicts the state of health (SoH) and remaining useful life (RUL) of the battery with high accuracy by learning complex degradation patterns, and can thus optimize battery replacement timing and maintenance plans and contribute to extending battery life and reducing operating costs.

### Description of Reference Numerals

1: Deep learning-based state of health and remaining useful life prediction system

2: Communication network

3: Battery management system

4: Personal computer

9: Input unit

10: Processor

11: Communication unit

12: Database

13: Output unit

What is claimed is:

1. A system for predicting a state of health and a remaining useful life of a battery based on deep learning, comprising:
a database configured to store first aggregate data including multiple battery data collected from an input unit; and
a processor configured to preprocess the first aggregate data based on a first artificial intelligence model, train a second artificial intelligence model with the preprocessed first aggregate data as input, and predict a state of health (SoH) and a remaining useful life (RUL) of a battery based on the second artificial intelligence model that has completed training,
wherein the processor comprises:
a preprocessing unit configured to preprocess the first aggregate data by converting the first aggregate data into a spectrogram and denoising based on the first artificial intelligence model;
a training unit configured to extract features with the preprocessed first aggregate data as input, and proceed with training the second artificial intelligence model to estimate the state of health based on the extracted features; and
a prediction unit configured to estimate the state of health and predict the remaining useful life from second aggregate data input by a user based on the second artificial intelligence model trained by the training unit.

2. The system of claim 1, wherein the first and second aggregate data comprise voltage, charge/discharge capacity, and current.

3. The system of claim 1, wherein the preprocessing unit converts the first aggregate data into a spectrogram by using a short-time Fourier transform (STFT).

4. The system of claim 3, wherein the preprocessing unit denoises the converted spectrogram data based on a denoising convolutional neural network (DnCNN).

5. The system of claim 1, wherein the training unit:
receives data generated by the preprocessing unit as input, and
extracts a feature vector and trains the second artificial intelligence model to estimate the state of health (SoH) based on the feature vector.

6. The system of claim 5, wherein the training unit optimizes hyperparameters, including a learning rate, a dropout rate, and a batch size, by applying Bayesian optimization in a process of training the second artificial intelligence model.

7. The system of claim 1, wherein the prediction unit:
based on the second artificial intelligence model trained by the training unit,
estimates the state of health (SoH) in real time from the second aggregate data input by the user, and
predicts the remaining useful life (RUL) based on a result of estimating the state of health.

8. A method of predicting a state of health and a remaining useful life of a battery based on deep learning, comprising:
storing multiple data received from an input unit as first aggregate data;
converting the first aggregate data into a spectrogram;
preprocessing and denoising data by inputting the converted spectrogram data into a first artificial intelligence model;
proceeding with training a second artificial intelligence model to estimate a state of health (SoH) of a battery by inputting the denoised data into the second artificial intelligence model; and
estimating the state of health (SoH) and predicting a remaining useful life (RUL) of the battery from second aggregate data input by a user based on the trained second artificial intelligence model.

9. The method of claim 8, wherein the converting into the spectrogram converts the first aggregate data into two-dimensional data including time-frequency domain features based on a short-time Fourier transform (STFT).

10. The method of claim 8, wherein the first artificial intelligence model is a denoising convolutional neural network that applies a residual learning technique.

11. The method of claim 10, wherein the first artificial intelligence model comprises at least one of a denoising convolutional neural network (DnCNN), a flexible and fast denoising network (FFDNet), and a memory network (MemNet).

12. The method of claim 8, wherein the second artificial intelligence model comprises at least one of a convolutional neural network (CNN), a recurrent neural network (RNN), a variational autoencoder (VAE), and a transformer.

13. A system for predicting a state of health and a remaining useful life of a battery based on deep learning, comprising:
a database configured to store first aggregate data including multiple data received from an input unit;
a processor configured to convert the first aggregate data into a spectrogram, denoise by inputting the converted spectrogram data into a first artificial intelligence model, estimate a state of health (SoH) of a battery by inputting the denoised first aggregate data into a second artificial intelligence model, and predict a remaining useful life (RUL) of the battery; and
an output unit configured to output a result of predicting the state of health (SoH) and the remaining useful life (RUL) from second aggregate data input by a user based on the first and second artificial intelligence models that have been trained.

14. The system of claim 13, wherein the processor:
detects a deterioration in battery health based on the result of predicting the state of health (SoH), and provides a detection result.

15. The system of claim 13, wherein the processor:
generates a battery maintenance plan including battery replacement timing based on the result of predicting the remaining useful life (RUL), and provides the generated maintenance plan.
